(19) United States
(12) Patent Application Publication
(10) Pub. No.: US 2013/0134551 A1
(43) Pub. Date: May 30, 2013

(54) INDUCTORS IN SEMICONDUCTOR DEVICES AND METHODS OF FORMING THE SAME

(71) Applicant: Yang-Nam Kim, Hwaseong-si (KR)

(72) Inventor: Yang-Nam Kim, Hwaseong-si (KR)

(73) Assignee: SAMSUNG ELECTRONICS CO., LTD., Suwon-si (KR)

(21) Appl. No.: 13/538,388

(22) Filed: Jun. 29, 2012

(30) Foreign Application Priority Data
Nov. 25, 2011 (KR) 1020110124205

(51) Int. Cl. H01L 27/22

(52) U.S. Cl. 257/531; 257/E27.005

(57) ABSTRACT

An inductor in a semiconductor device may include a first interconnection line on a substrate; a second interconnection line on the first interconnection line; first and second common interconnection lines on the second interconnection line; a first via connecting a first end of the first interconnection line to a first end of the first common interconnection line; a second via connecting a second end of the first interconnection line to a second end of the second common interconnection line; a third via connecting a first end of the second interconnection line to the first end of the first common interconnection line; and a fourth via connecting a second end of the second interconnection line to the second end of the second common interconnection line. The first and second interconnection lines and the first and second common interconnection lines may extend in a direction parallel to a surface of the substrate.

### CROSS-REFERENCE TO RELATED APPLICATION(S)

This application claims priority from Korean Patent Application No. 10-2011-0124205, filed on Nov. 25, 2011, in the Korean Intellectual Property Office (KIPO), the entire contents of which are incorporated herein by reference.

### BACKGROUND

1. Field

Example embodiments relate to semiconductors and methods of forming the same. Example embodiments also relate to inductors in semiconductor devices and methods of forming the same.

2. Description of Related Art

In general, inductors of a semiconductor device may be formed using a topmost metal layer. The topmost metal layer used as the inductors may be formed to have a coil shape, for example, a spiral shape. The coil-shaped metal layer may be formed in a plane which is parallel with a semiconductor substrate. Thus, a central portion of the coil-shaped metal layer may be disposed to be close to the semiconductor substrate. Accordingly, if a current flows through the coil-shaped metal layer, an image current may be induced in the semiconductor substrate and the image current may affect a magnetic field generated in the central portion of the coil-shaped metal layer. Consequently, the efficiency and/or the performance of the planar inductors may be degraded. Further, the planar inductors may generate parasitic signals that affect semiconductor elements formed around the planar inductors. Hence, the planar inductors may cause malfunction of the semiconductor device.

In addition, the planar inductors may be two dimensionally formed a single plane parallel with the semiconductor substrate. Thus, a large planar area may be required to form an inductor having high impedance. That is, there may be limitations in reducing a planar area that the inductor occupies. Accordingly, it may be difficult to increase the integration density of the semiconductor device.

### SUMMARY

Example embodiments may provide inductors in a semiconductor device and methods of forming the same.

According to some example embodiments, an inductor in a semiconductor device may include a first interconnection line on a substrate; a second interconnection line on the first interconnection line; first and second common interconnection lines on the second interconnection line, where the first and second common interconnection lines are adjacent to each other; a first via connecting a first end of the first interconnection line to a first end of the first common interconnection line; a second via connecting a second end of the first interconnection line to a second end of the second common interconnection line; a third via connecting a first end of the second interconnection line to the first end of the first common interconnection line; and/or a fourth via connecting a second end of the second interconnection line to the second end of the second common interconnection line. The first interconnection line, the second interconnection line, and/or the first and second common interconnection lines may extend in a first direction that is parallel to a surface of the substrate.

According to some example embodiments, the inductor may further include a first protrusion extending from the first end of the first interconnection line in a second direction intersecting the first direction. The first common interconnection line may be electrically connected to the first interconnection line through the first protrusion and/or the first via.

According to some example embodiments, the inductor may further include a second protrusion extending from the first end of the second interconnection line in a second direction intersecting the first direction. The first common interconnection line may be electrically connected to the second interconnection line through the second protrusion and/or the first via.

According to some example embodiments, the inductor may further include a third protrusion and/or a fourth protrusion extending from the second end of the second common interconnection line in a second direction intersecting the first direction. The second common interconnection line may be electrically connected to the first interconnection line through the fourth protrusion and the second via. The second common interconnection line may be electrically connected to the second interconnection line through the third protrusion and/or the fourth via.

According to some example embodiments, each of the first and second vias may include an upper via, a lower via, and a connector between the upper and lower vias. The connector may be at a same level as the second interconnection line. The connector may be spaced apart from second interconnection line.

According to some example embodiments, the inductor may further include an inductor core under the first and second common interconnection lines. The inductor core may be spaced apart from the first and second common interconnection lines. The inductor core may be spaced apart from the first to fourth vias.

According to some example embodiments, the inductor core may be between the first interconnection line and the second interconnection line, or between the second interconnection line and the first and second common interconnection lines.

According to some example embodiments, the inductor core may include ferromagnetic material.

According to some example embodiments, an inductor in a semiconductor device may include a first interconnection line on a substrate; a second interconnection line on the first interconnection line; third and fourth interconnection lines on the second interconnection line; fifth and sixth interconnection lines on the third and fourth interconnection lines; a first via connecting a first end of the first interconnection line to a first end of the fifth interconnection line; a second via connecting a second end of the first interconnection line to a second end of the sixth interconnection line; a third via connecting a first end of the second interconnection line to a first end of the third interconnection line; and/or a fourth via connecting a second end of the second interconnection line to a second end of the fourth interconnection line. The first to sixth interconnection lines may extend in a first direction that is parallel to a surface of the substrate.

According to some example embodiments, the inductor may further include a first protrusion extending from the first end of the first interconnection line in a second direction intersecting the first direction. The first interconnection line may be electrically connected to the fifth interconnection line through the first protrusion and/or the first via.

According to some example embodiments, the inductor may further include a second protrusion extending from the first end of the second interconnection line in a second direction intersecting the first direction. The second interconnection line may be electrically connected to the third interconnection line through the second protrusion and/or the third via.

According to some example embodiments, the inductor may further include a third protrusion extending from the second end of the fourth interconnection line in a second direction intersecting the first direction. The second interconnection line may be electrically connected to the fourth interconnection line through the third protrusion and/or the fourth via.

According to some example embodiments, the inductor may further include a fourth protrusion extending from the second end of the sixth interconnection line in a second direction intersecting the first direction. The first interconnection line may be electrically connected to the sixth interconnection line through the fourth protrusion and/or the second via.

According to some example embodiments, the inductor may further include an inductor core between the second and third interconnection lines. The inductor core may be spaced apart from the first to sixth interconnection lines. The inductor core may be spaced apart from the first to fourth vias.

According to some example embodiments, the inductor core may include ferromagnetic material.

According to some example embodiments, an inductor in a semiconductor device may include a first spiral structure; and/or a second spiral structure. The first spiral structure may include a first interconnection line on a substrate; first and second common interconnection lines adjacent to each other; a first via connecting a first end of the first interconnection line to a first end of the first common interconnection line; and/or a second via connecting a second end of the first interconnection line to a second end of the second common interconnection line. The second spiral structure may include a second interconnection line on the first interconnection line; the first and second common interconnection lines; a third via connecting a first end of the second interconnection line to the first end of the first common interconnection line; and/or a fourth via connecting a second end of the second interconnection line to the second end of the second common interconnection line. The first and second common interconnection lines may be on the second interconnection line.

According to some example embodiments, a first distance, from the first end of the first interconnection line to the second end of the first interconnection line, may be greater than a second distance, from the first end of the second interconnection line to the second end of the second interconnection line.

According to some example embodiments, a cross-sectional area of the first spiral structure may be greater than a cross-sectional area of the second spiral structure.

According to some example embodiments, the inductor may further include an inductor core between the first interconnection line and the second interconnection line, or between the second interconnection line and the first and second common interconnection lines.

According to some example embodiments, the first spiral structure may at least partially surround the inductor core and/or the second spiral structure may at least partially surround the inductor core.

### BRIEF DESCRIPTION OF THE DRAWINGS

The above and/or other aspects and advantages will become more apparent and more readily appreciated from the following detailed description of example embodiments, taken in conjunction with the accompanying drawings, in which:

FIG. 1A is a perspective view illustrating an inductor according to some example embodiments.

FIG. 1B is a top plan view of the inductor viewed along a Z-axis of FIG. 1A.

FIG. 1C is a front view of the inductor viewed along a Y-axis of FIG. 1A.

FIG. 1D is a side view of the inductor viewed along an X-axis of FIG. 1A.

FIGS. 2A to 2E are perspective views illustrating a method of forming an inductor according to some example embodiments.

FIG. 3A is a perspective view illustrating an inductor according to some example embodiments.

FIG. 3B is a front view of the inductor viewed along a Y-axis of FIG. 3A.

FIG. 3C is a side view of the inductor viewed along an X-axis of FIG. 3A.

FIG. 4A is a perspective view illustrating an inductor according to some example embodiments.

FIG. 4B is a top plan view of the inductor viewed along a Z-axis of FIG. 4A.

FIG. 4C is a front view of the inductor viewed along a Y-axis of FIG. 4A.

FIG. 4D is a side view of the inductor viewed along an X-axis of FIG. 4A.

FIGS. 5A to 5G are perspective views illustrating a method of forming an inductor according to some example embodiments.

FIG. 6A is a perspective view illustrating an inductor according to some example embodiments.

FIG. 6B is a front view of the inductor viewed along a Y-axis of FIG. 6A.

FIG. 6C is a side view of the inductor viewed along an X-axis of FIG. 6A.

### DETAILED DESCRIPTION

Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

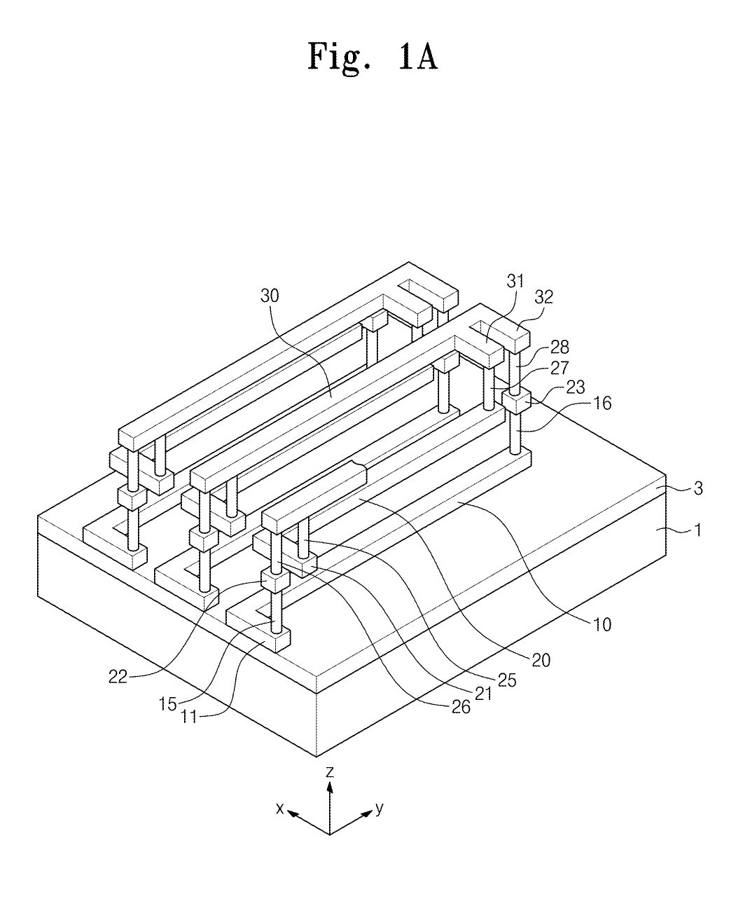

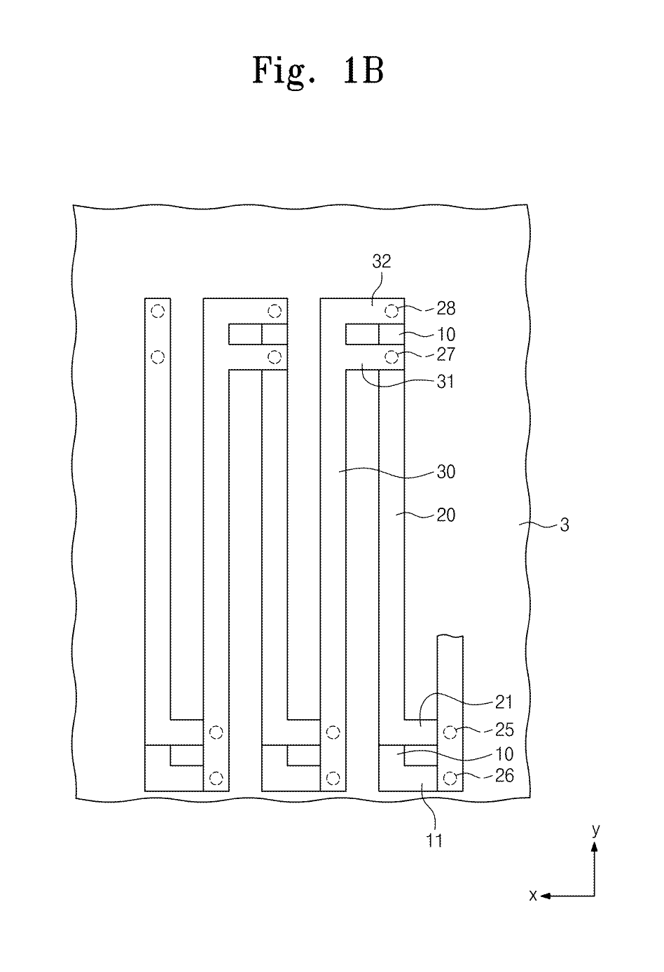

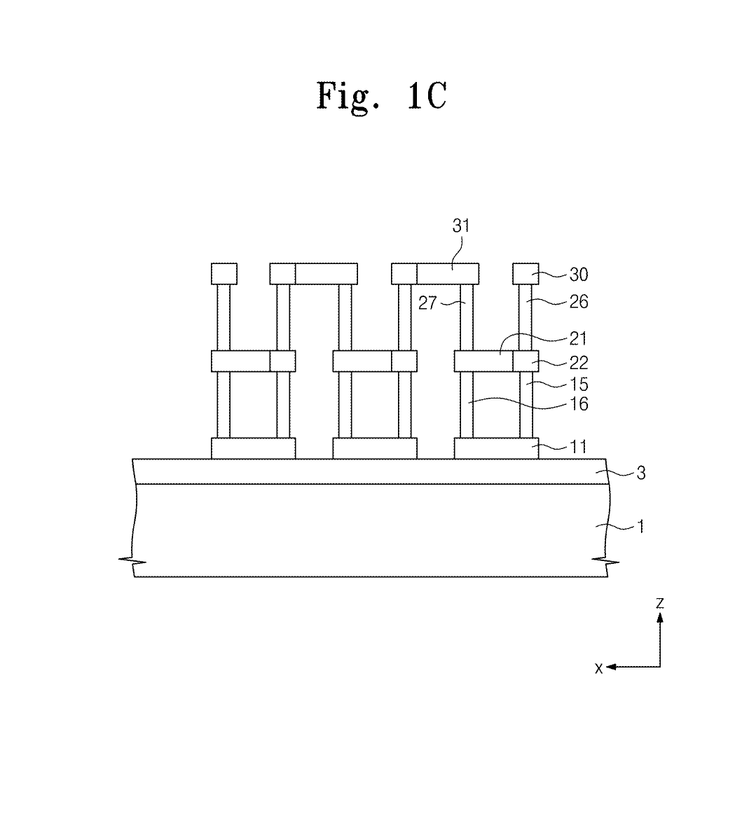

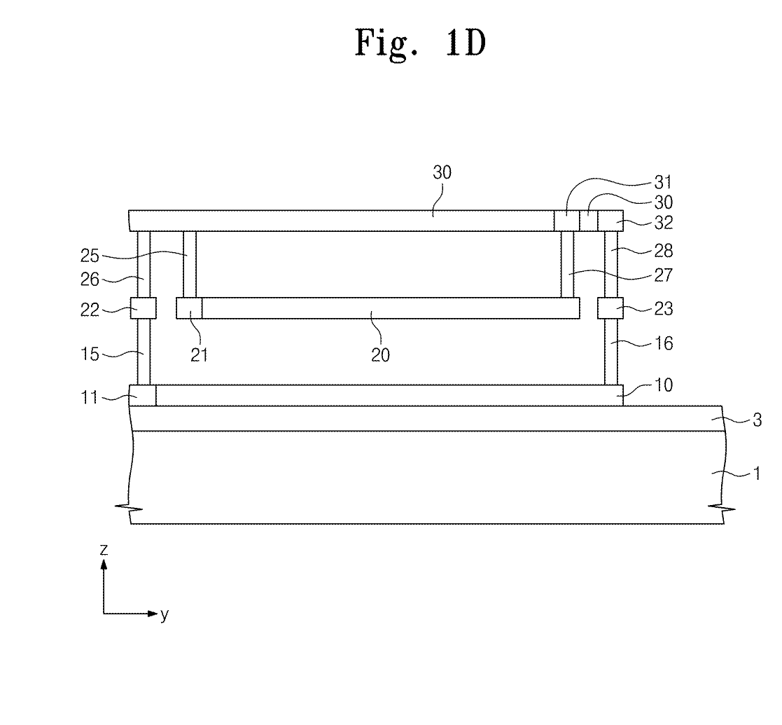

FIG. 1A is a perspective view illustrating an inductor according to some example embodiments. FIG. 1B is a top plan view of the inductor viewed along a Z-axis of FIG. 1A. FIG. 1C is a front view of the inductor viewed along a Y-axis of FIG. 1A. FIG. 1D is a side view of the inductor viewed along an X-axis of FIG. 1A.

Referring to FIG. 1A, a substrate 1 may be provided. The substrate 1 may be a semiconductor substrate. An insulation layer 3 may be disposed on the substrate 1.

First interconnection lines 10, second interconnection lines 20 and common interconnection lines 30 may be sequentially stacked on the insulation layer 3. The first, second and common interconnection lines 10, 20 and 30 may be metal patterns such as copper patterns, aluminum patterns and/or tungsten patterns.

The first, second and common interconnection lines 10, 20 and 30 may be disposed at different levels from one another. For example, the second interconnection lines 20 may be disposed above the first interconnection lines 10 and the common interconnection lines 30 may be disposed above the second interconnection lines 20. Each of the first, second and common interconnection lines 10, 20 and 30 may be disposed to have a desired (or alternatively, predetermined) width in an X-axis direction and to extend in a Y-axis direction. The first interconnection lines 10 may be spaced apart from each other and may be arrayed in the X-axis direction. Similarly, the second interconnection lines 20 may be spaced apart from each other and may be arrayed in the X-axis direction. Further, the common interconnection lines 30 may be spaced apart from each other and may be arrayed in the X-axis direction.

Each of the first, second and common interconnection lines 10, 20 and 30 may have a first end and a second end opposite to the first end. First protrusions 11 may be disposed to extend from respective ones of the first ends of the first interconnection lines 10 in the X-axis direction. Similarly, second protrusions 21 may be disposed to extend from respective ones of the first ends of the second interconnection lines 20 in the X-axis direction. Further, a third protrusion 31 and a fourth protrusion 32 may be disposed to extend from the second end of each of the common interconnection lines 30 in the X-axis direction. The third protrusions 31 and/or the fourth protrusions 32 may extend in the same direction and may be spaced apart from each other.

Interlayer insulation layers may be disposed between the first, second and/or common interconnection lines 10, 20 and 30. However, the interlayer insulation layers are not shown in FIGS. 1A, 1B, 1C and 1D in order to clearly illustrate an internal structure of the inductor.

The first, second and common interconnection lines 10, 20 and 30 may be disposed to be parallel with the substrate 1, as illustrated in FIGS. 1A, 1B, 1C and 1D. However, the inventive concept may not be limited to the above description.

The first, second and common interconnection lines 10, 20 and 30 may be electrically connected to each other through first and second lower vias 15 and 16 and first to fourth upper vias 25, 26, 27 and 28. Each of the first and second lower vias 15 and 16 and the first to fourth upper vias 25, 26, 27 and 28 may include metal material such as copper, aluminum and/or tungsten.

First connectors 22 may be disposed between the first lower vias 15 and the second upper vias 26. The first connectors 22 may be disposed at the same level as the second interconnection lines 20 and may be spaced apart from the second interconnection lines 20. The first connectors 22 may electrically connect the first lower vias 15 to the second upper vias 26.

Second connectors 23 may be disposed between the second lower vias 16 and the fourth upper vias 28. The second connectors 23 may be disposed at the same level as the second interconnection lines 20 and may be spaced apart from the second interconnection lines 20. The second connectors 23 may electrically connect the second lower vias 16 to the fourth upper vias 28. Each of the first and second connectors 22 and 23 may include metal material such as copper, aluminum and/or tungsten.

The first interconnection lines 10 may be electrically connected to the common interconnection lines 30.

In some example embodiments, the first end of the first interconnection line 10 may be electrically connected to the first end of the common interconnection line 30 on the first interconnection line 10 through the first protrusion 11, the first lower via 15, the first connector 22, and the second upper via 26. The second end of the first interconnection line 10 may be electrically connected to the second end of another common interconnection line 30 adjacent to the common interconnection line 30 on the first interconnection line 10 through the second lower via 16, the second connector 23, the fourth upper via 28, and the fourth protrusion 32. Thus, the plurality of first interconnection lines 10 and the plurality of common interconnection lines 30 may be connected to each other through the vias 15, 16, 26 and 28 and the connectors 22 and 23, thereby constituting a first spiral structure. A plane surrounded by each loop of the first spiral structure may be substantially perpendicular to the substrate 1.

The second interconnection lines 20 may be electrically connected to the common interconnection lines 30.

In some example embodiments, the first end of the second interconnection line 20 may be electrically connected to the first end of the common interconnection line 30 on the second interconnection line 20 through the second protrusion 21 and the first upper via 25. The second end of the second interconnection line 20 may be electrically connected to the second end of another common interconnection line 30 adjacent to the common interconnection line 30 on the second interconnection line 20 through the third upper via 27 and the third protrusion 31. Thus, the plurality of second interconnection lines 20 and the plurality of common interconnection lines 30 may be connected to each other through the vias 25 and 27, thereby constituting a second spiral structure. A plane surrounded by each loop of the second spiral structure may be substantially perpendicular to the substrate 1.

Alternatively, the first, second and common interconnection lines 10, 20 and 30 may be connected to each other through the vias without use of the first to fourth protrusions 11, 21, 31 and 32. Accordingly, the connection structure of the first, second and common interconnection lines 10, 20 and 30 may be embodied in many different forms.

As illustrated in FIGS. 1B and 1C, the second interconnection lines 20 may be disposed to overlap with the first interconnection lines 10 in a plan view. The common interconnection lines 30 may be disposed between the first interconnection lines 10 and the second interconnection lines 20 in a plan view. Thus, the first interconnection lines 10 and the common interconnection lines 30 may be serially connected to each other to constitute the first spiral structure, and the second interconnection lines 20 and the common interconnection lines 30 may be serially connected to each other to constitute the second spiral structure.

Alternatively, the second interconnection lines 20 may be disposed to overlap with the first interconnection lines 10 in a plan view, and the common interconnection lines 30 may be disposed to overlap with the second interconnection lines 20 in a plan view. However, the example embodiments may not be limited to the above description. That is, the connection structure of the first, second and common interconnection lines 10, 20 and 30 may be embodied in many different forms.

Consequently, the first interconnection lines 10 and the common interconnection lines 30 may be serially connected to each other to constitute the first spiral structure, and the second interconnection lines 20 and the common interconnection lines 30 may be serially connected to each other to constitute the second spiral structure.

Referring to FIG. 1D, the second interconnection lines 20 may be shorter in length than the first interconnection lines 10 and the common interconnection lines 30. Thus, the second spiral structure composed of the second and common interconnection lines 20 and 30 may be disposed in the first spiral structure composed of the first and common interconnection lines 10 and 30.

Referring again to FIG. 1A, the first, second and common interconnection lines 10, and 30 may be disposed to constitute vertical type spiral structures. That is, the first interconnection lines 10 and the common interconnection lines 30 may constitute the first vertical type spiral structure, and the second interconnection lines 20 and the common interconnection lines 30 may constitute the second vertical type spiral structure. Thus, the first, second and common interconnection lines 10, 20 and 30 may constitute a double spiral structure.

The interconnection lines 10, 20 and 30, the vias 15, 16, 25, 26, 27 and 28, and the connectors 22 and 23 may constitute a coil-shaped structure, and both terminals of the coil-shaped structure may be connected to circuits. Thus, the coil-shaped structure may act as an inductor.

The inductor according to the above example embodiment may have coils which are substantially perpendicular to the substrate 1. Thus, semiconductor elements (e.g., transistors or the like) formed around the inductor may be less influenced by electrical signals flowing through the inductor. Further, a planar area that the vertical type inductor occupies may be minimized to increase the integration density of a semiconductor device and/or to provide a high inductance in a limited planar area.

The inductor according to the above example embodiment may be formed to have vertical coils, as described above. Thus, the intensity of the magnetic field generated from the inductor may be increased to improve the efficiency of the inductor.

The inductor illustrated in FIGS. 1A to 1D may provide a double spiral structure. However, the inventive concept may not be limited to example embodiments illustrated in FIGS. 1A to 1D. For example, some interconnection lines may be additionally disposed above the first interconnection lines 10, the second interconnection lines 20, and/or the common interconnection lines 30 to constitute a multi-spiral structure.

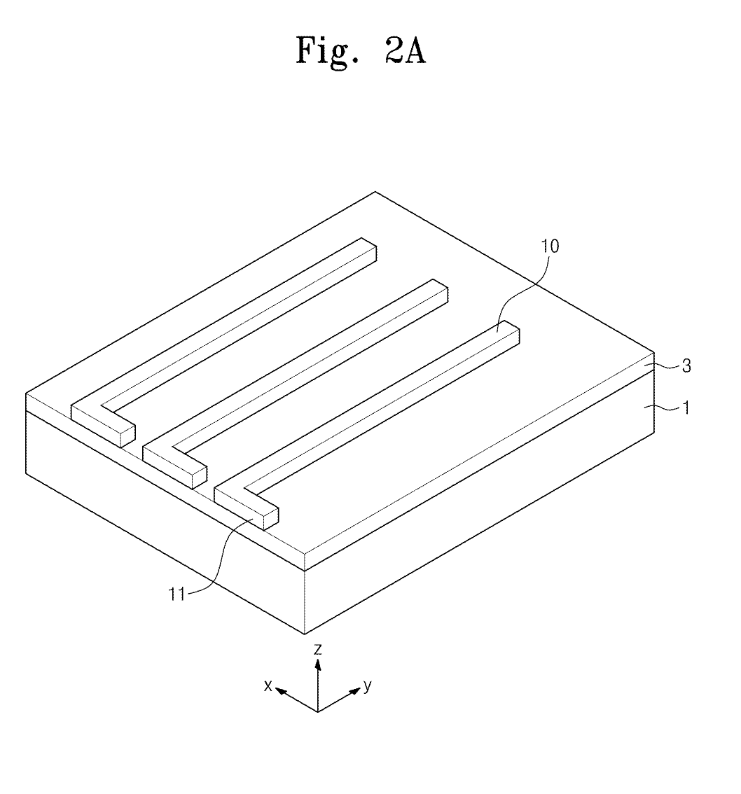

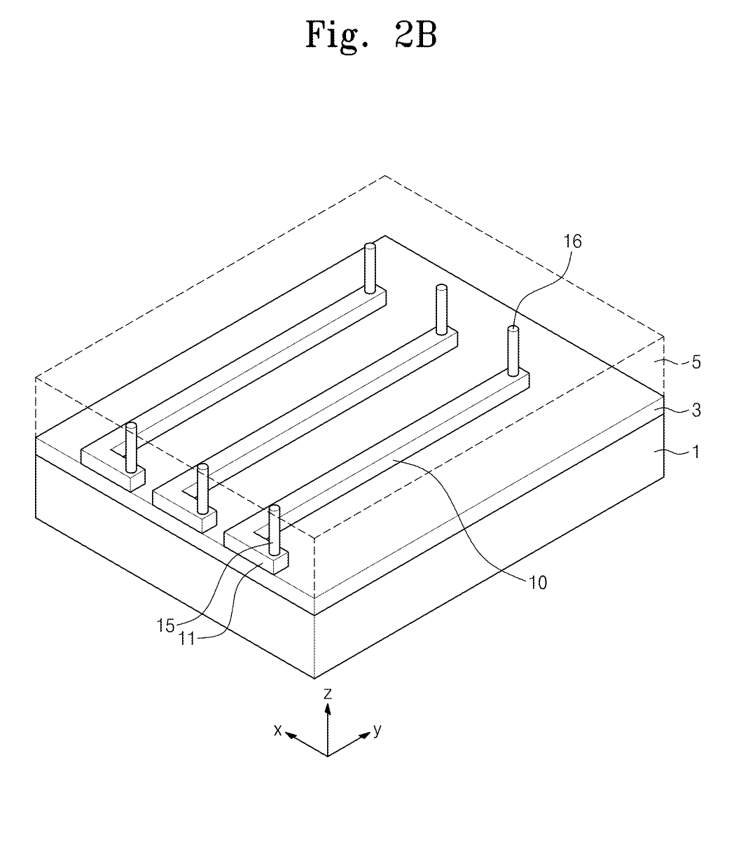

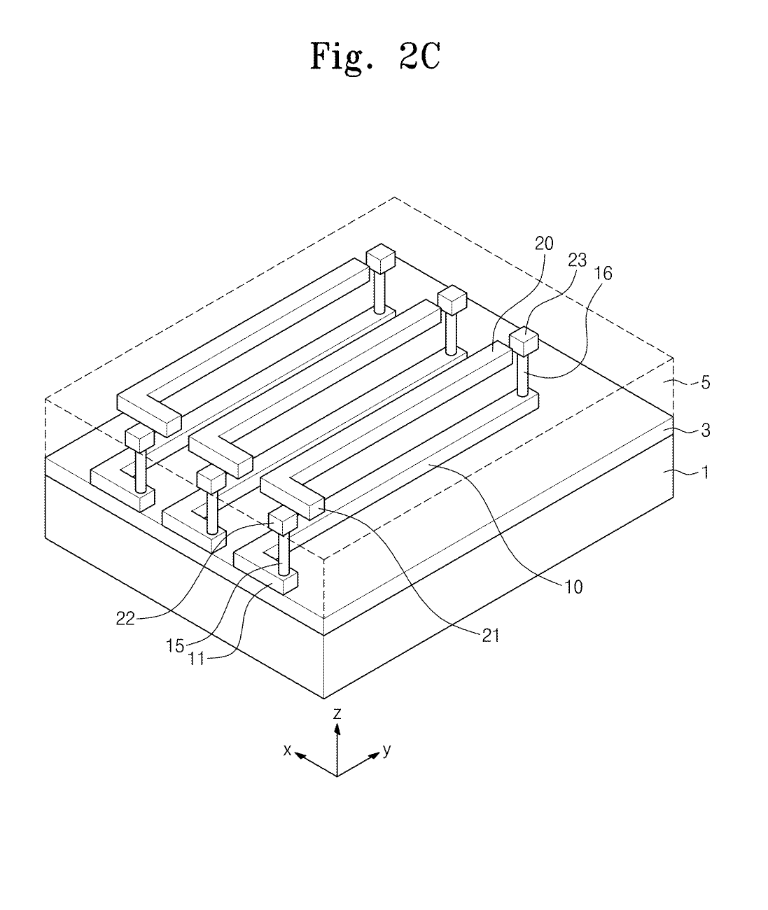

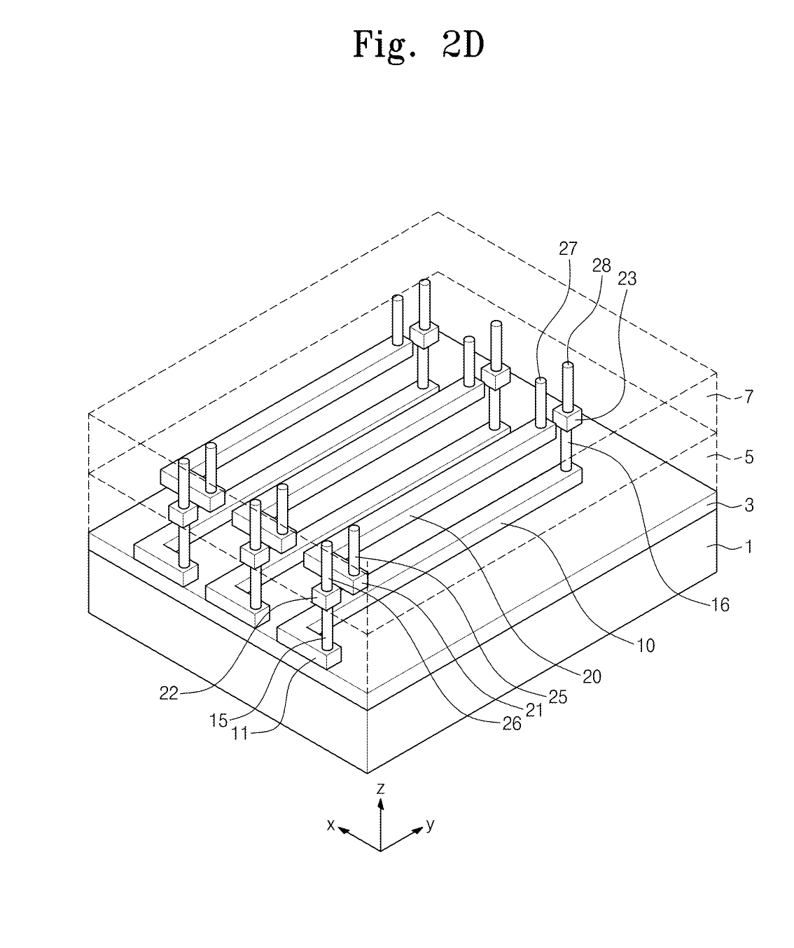

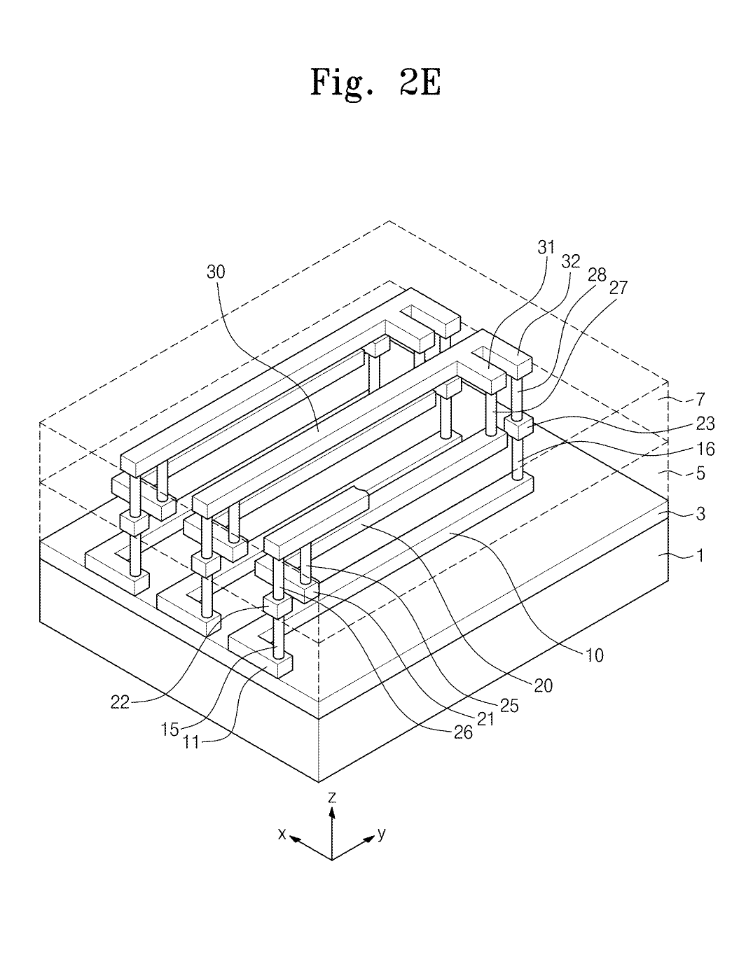

FIGS. 2A to 2E are perspective views illustrating a method of forming an inductor according to some example embodiments.

Referring to FIG. 2A, an insulation layer 3 may be formed on a substrate 1. A plurality of first interconnection lines 10 may be formed on the insulation layer 3. Each of the first interconnection lines 10 may have a desired (or alternatively, predetermined) width in an X-axis direction and may extend in a Y-axis direction. That is, the first interconnection lines 10 may be disposed to be parallel with the Y-axis direction. The first interconnection lines 10 may be arrayed in the X-axis direction and may be spaced apart from each other.

Each of the first interconnection lines 10 may have a first end and a second end opposite to the first end. First protrusions 11 may be disposed to extend from respective ones of the first ends of the first interconnection lines 10 in the X-axis direction.

The first interconnection lines 10 and the first protrusions 11 may be formed by depositing a conductive layer on the insulation layer 3 and by patterning the conductive layer. That is, the first interconnection lines 10 and the first protrusions 11 may be simultaneously formed. The conductive layer may be formed using a deposition process or a sputtering process.

Referring to FIG. 2B, a first interlayer insulation layer 5 may be formed to cover the first interconnection lines 10 and the first protrusions 11.

First lower vias 15 and second lower vias 16 may be formed to penetrate the first interlayer insulation layer 5. The first lower vias 15 and the second lower vias 16 may be formed by patterning the first interlayer insulation layer 5 to form via holes penetrating the first interlayer insulation layer 5, forming a conductive layer in the via holes and on the first interlayer insulation layer 5, and planarizing the conductive layer until the first interlayer insulation layer 5 is exposed.

In some example embodiments, the first lower vias 15 may be formed on respective ones of the first protrusions 11 and may be electrically connected to respective ones of the first interconnection lines 10. The second lower vias 16 may be formed on respective ones of the second ends of the first interconnection lines 10 and may be electrically connected to respective ones of the first interconnection lines 10. The first and second lower vias 15 and 16 may be simultaneously formed.

Referring to FIG. 2C, a plurality of second interconnection lines 20 may be formed on the first interlayer insulation layer 5. Each of the second interconnection lines 20 may have a desired (or alternatively, predetermined) width in the X-axis direction and may extend in the Y-axis direction. That is, the second interconnection lines 20 may be disposed to be parallel with the Y-axis direction. The second interconnection lines 20 may be arrayed in the X-axis direction and may be spaced apart from each other. The second interconnection lines 20 may be formed to overlap with respective ones of the first interconnection lines 10 in a plan view.

Each of the second interconnection lines 20 may have a first end and a second end opposite to the first end. Second protrusions 21 may be disposed to extend from respective ones of the first ends of the second interconnection lines 20 in the X-axis direction.

Further, first connectors 22 may be formed on the first interlayer insulation layer 5. The first connectors 22 may be formed to contact respective ones of the first lower vias 15. That is, the first connectors 22 may be electrically connected to respective ones of the first lower vias 15. In some example embodiments, the first connectors 22 may be formed to be adjacent to the second protrusions 21 and to be spaced apart from the second protrusions 21.

In addition, second connectors 23 may be formed on the first interlayer insulation layer 5. The second connectors 23 may be formed to contact respective ones of the second lower vias 16. That is, the second connectors 23 may be electrically connected to respective ones of the second lower vias 16. In some example embodiments, the second connectors 23 may be formed to be adjacent to the second ends of the second interconnection lines 20 and to be spaced apart from the second ends of the second interconnection lines 20.

The second interconnection lines 20, the second protrusions 21, the first connectors 22 and the second connectors 23 may be formed by depositing a conductive layer on the first interlayer insulation layer 5 and by patterning the conductive layer. The conductive layer may be formed using a deposition process or a sputtering process. Alternatively, the second interconnection lines 20, the second protrusions 21, the first connectors 22 and the second connectors 23 may be formed in the first interlayer insulation layer 5 using a damascene process. The second interconnection lines 20, the first connectors 22 and the second connectors 23 may be simultaneously formed.

Referring to FIG. 2D, a second interlayer insulation layer 7 may be formed to cover the second interconnection lines 20, the first connectors 22 and the second connectors 23.

First upper vias 25, second upper vias 26, third upper vias 27 and fourth upper vias 28 may be formed to penetrate the second interlayer insulation layer 7. The first to fourth upper vias 25, 26, 27 and 28 may be formed by patterning the second interlayer insulation layer 7 to form via holes penetrating the second interlayer insulation layer 7, forming a conductive layer in the via holes and on the second interlayer insulation layer 7, and planarizing the conductive layer until the second interlayer insulation layer 7 is exposed.

In some example embodiments, the first upper vias 25 may be formed on respective ones of the second protrusions 21 and may be electrically connected to respective ones of the second interconnection lines 20. The second upper vias 26 may be formed on respective ones of the first connectors 22 and may be electrically connected to respective ones of the first connectors 22. The third upper vias 27 may be formed on respective ones of the second ends of the second interconnection lines 20 and may be electrically connected to respective ones of the second interconnection lines 20. The fourth upper vias 28 may be formed on respective ones of the second connectors 23 and may be electrically connected to respective ones of the second connectors 23. The first to fourth upper vias 25, 26, 27 and 28 may be simultaneously formed.

Referring to FIG. 2E, a plurality of common interconnection lines 30 may be formed on the second interlayer insulation layer 7. Each of the common interconnection lines 30 may have a desired (or alternatively, predetermined) width in the X-axis direction and may extend in the Y-axis direction. That is, the common interconnection lines 30 may be formed to be parallel with the Y-axis direction. The common interconnection lines 30 may be arrayed in the X-axis direction and may be spaced apart from each other.

The common interconnection lines 30 may be formed to contact the first and second upper vias 25 and 26. Thus, each of the common interconnection lines 30 may be electrically connected to one of the first interconnection lines 10 through the second upper via 26, the first connector 22, the first lower via 15 and the first protrusion 11. Further, each of the common interconnection lines 30 may be electrically connected to one of the second interconnection lines 20 through the first upper via 25 and the second protrusion 21.

Each of the common interconnection lines 30 may have a first end and a second end opposite to the first end. A third protrusion 31 and a fourth protrusion 32 may be disposed to extend from the second end of each of the common interconnection lines 30 in the X-axis direction. The third and fourth protrusions 31 and 32 may be disposed above the second ends of the first and second interconnection lines 10 and 20. The third and fourth protrusions 31 and 32 may extend in the same direction and may be spaced apart from each other.

The third protrusions 31 may be formed to contact respective ones of the third upper vias 27 and may be electrically connected to respective ones of the second interconnection lines 20 through the third upper vias 27. The fourth protrusions 32 may be formed to contact respective ones of the fourth upper vias 28 and may be electrically connected to respective ones of the first interconnection lines 10 through the fourth upper vias 28, the second connectors 23 and the second lower vias 16.

The common interconnection lines 30, the third protrusions 31, and the fourth protrusions 32 may be formed by depositing a conductive layer on the second interlayer insulation layer 7 and by patterning the conductive layer. The conductive layer may be formed using a deposition process or a sputtering process. Alternatively, the common interconnection lines 30, the third protrusions 31 and the fourth protrusions 32 may be formed in the second interlayer insulation layer 7 using a damascene process. The common interconnection lines 30, the third protrusions 31 and the fourth protrusions 32 may be simultaneously formed.

As a result of the above processes, a coil-shaped structure may be formed, and both terminals of the coil-shaped structure may be connected to circuits. Thus, the coil-shaped structure may act as an inductor.

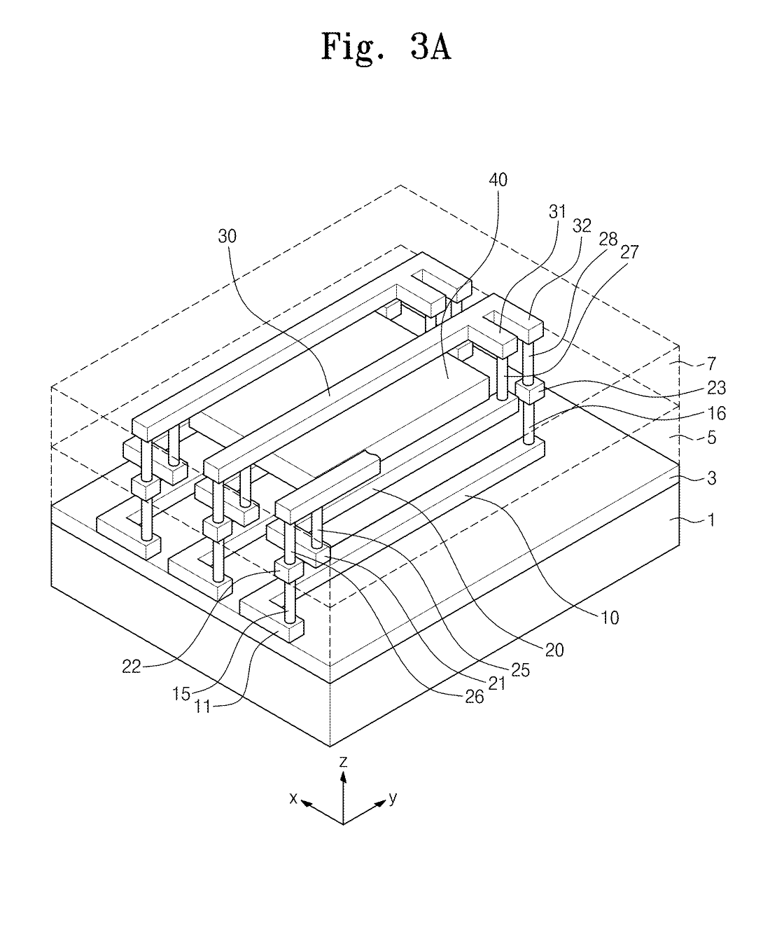

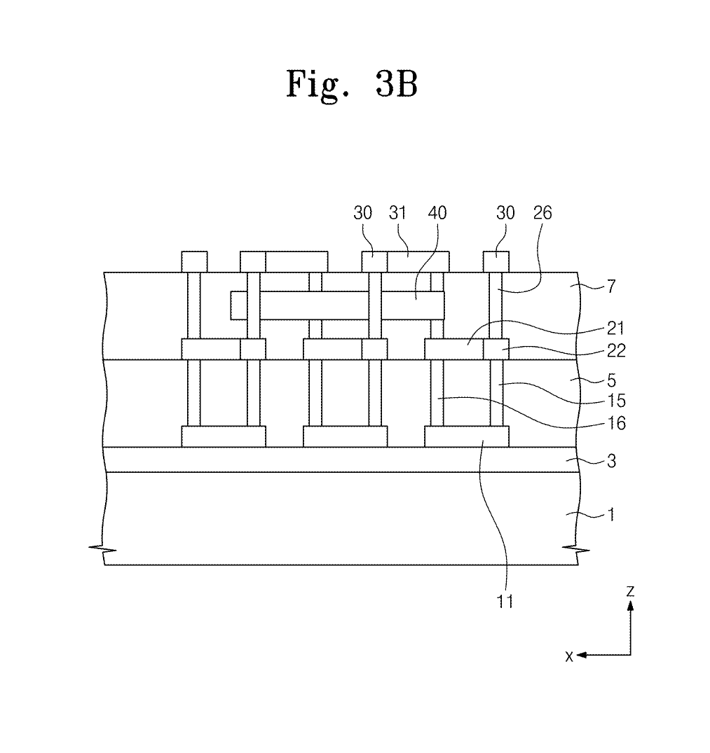

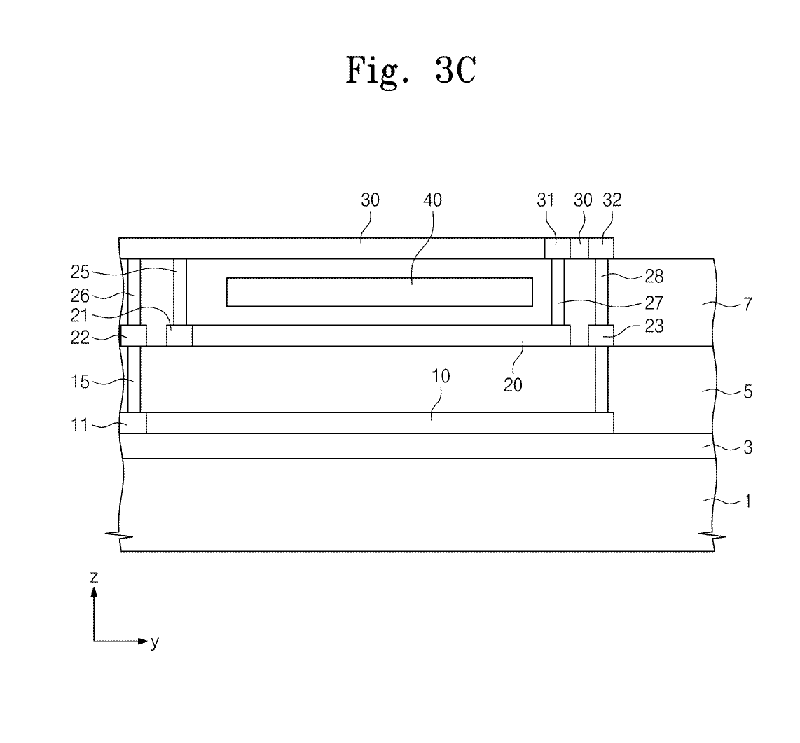

FIG. 3A is a perspective view illustrating an inductor according to some example embodiments. FIG. 3B is a front view of the inductor viewed along a Y-axis of FIG. 3A. FIG. 3C is a side view of the inductor viewed along an X-axis of FIG. 3A.

Referring to FIGS. 3A, 3B and 3C, an inductor according to example embodiments may have the similar structure to the inductor described with reference to FIGS. 1A, 1B, 1C, 1D, 2A, 2B, 2C, 2D and 2E. The inductor according to the example embodiment of FIGS. 3A, 3B and 3C may further include an inductor core 40 disposed in coils constituting the inductor as compared to the example embodiment illustrated in FIGS. 1A to 1D and FIGS. 2A to 2E. Thus, for the purpose of simplification in explanation, descriptions to the same components as illustrated in previous example embodiments will be omitted or briefly mentioned.

The inductor core 40 may include ferromagnetic material. For example, the inductor core 40 may include at least one of iron (Fe), cobalt (Co), nickel (Ni), tantalum (Ta), barium (Ba) and zinc (Zn). The inductor core 40 may be formed using an electro-plating process or a deposition process.

The inductor core 40 may be disposed in the second interlayer insulation layer 7. More specifically, the inductor core 40 may be disposed between the second interconnection lines 20 and the common interconnection lines 30. Alternatively, the inductor core 40 may be disposed in the first interlayer insulation layer 5. That is, the inductor core 40 may be disposed between the first interconnection lines 10 and the second interconnection lines 20.

The inductor core 40 may be surrounded by the coils constituting the spiral structure and may be spaced apart from the coils. That is, the inductor core 40 may be spaced apart from the first interconnection lines 10, the second interconnection lines 20, the common interconnection lines 30, and the vias 15, 16, 25, 26, 27 and 28.

According to example embodiments, the inductor core 40 may include ferromagnetic material. Thus, when a current flows through the inductor, magnetic dipoles in the inductor core 40 may be arrayed to be parallel with a specific direction. Accordingly, the inductance of the inductor may be increased.

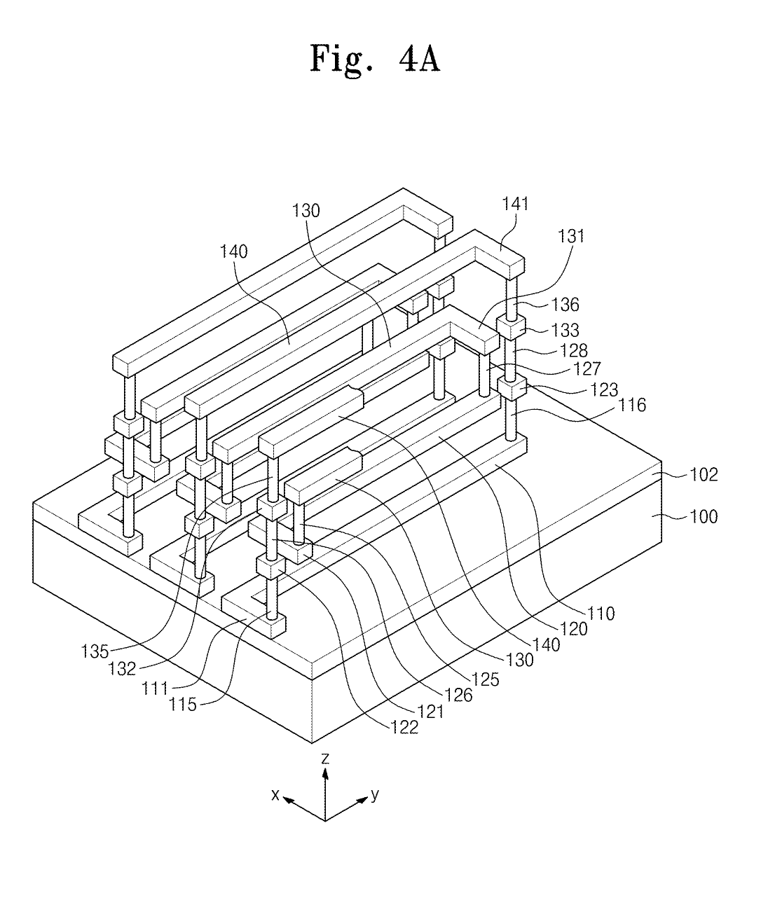

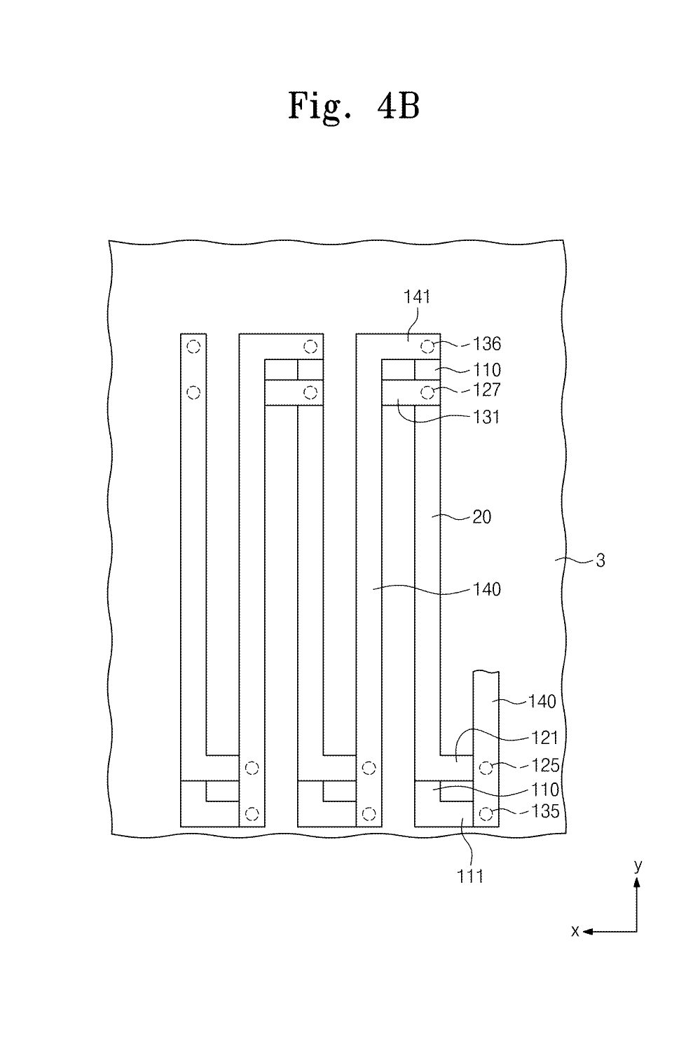

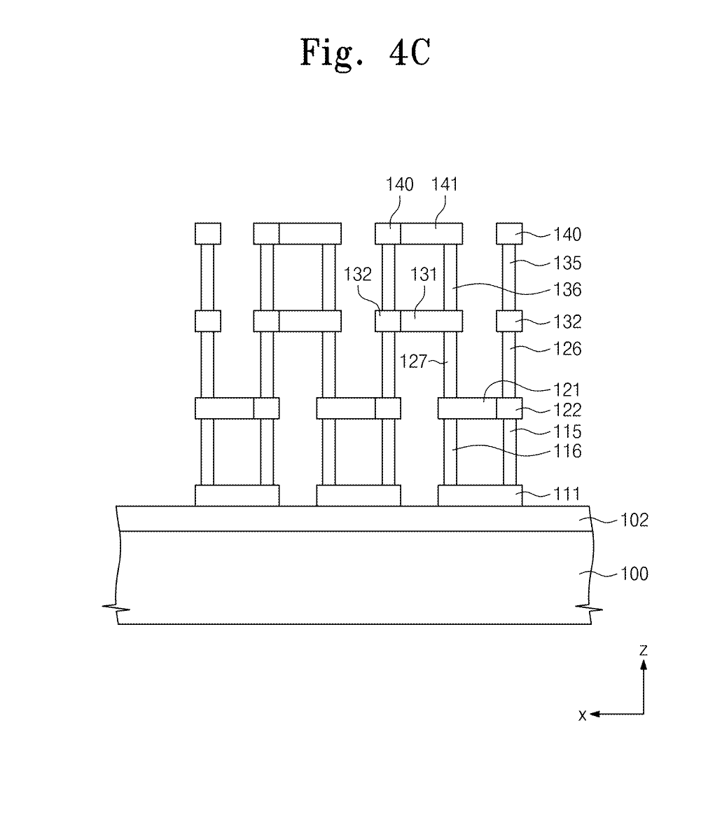

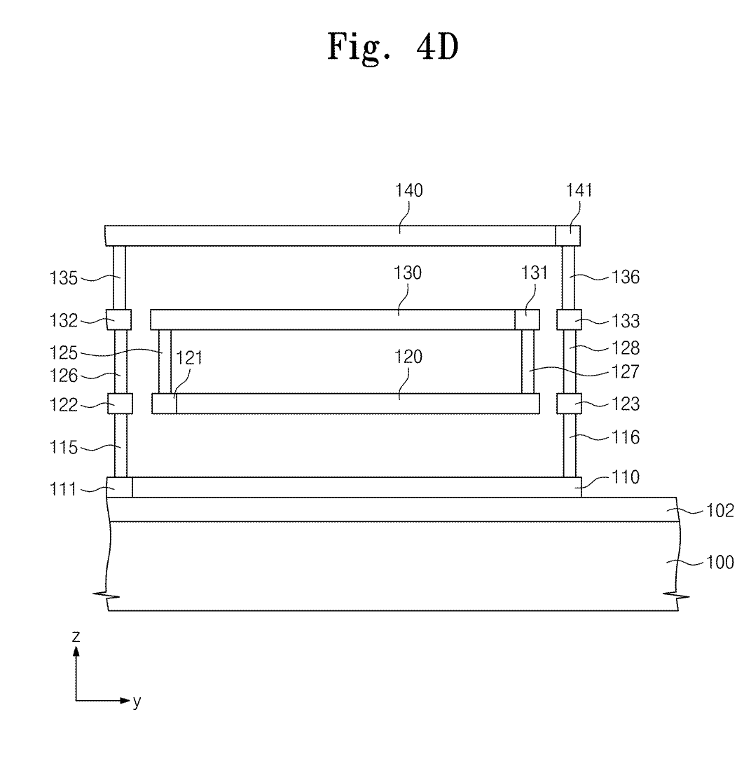

FIG. 4A is a perspective view illustrating an inductor according to some example embodiments. FIG. 4B is a top plan view of the inductor viewed along a Z-axis of FIG. 4A. FIG. 4C is a front view of the inductor viewed along a Y-axis of FIG. 4A. FIG. 4D is a side view of the inductor viewed along an X-axis of FIG. 4A.

Referring to FIG. 4A, an insulation layer 102 may be disposed on a substrate 100. First interconnection lines 110, second interconnection lines 120, third interconnection lines 130 and fourth interconnection lines 140 may be sequentially stacked on the insulation layer 102. The first to fourth interconnection lines 110, 120, 130 and 140 may be disposed at different levels from each other. For example, the second interconnection lines 120 may be disposed above the first interconnection lines 110, and the third interconnection lines 130 may be disposed above the second interconnection lines 120. Further, the fourth interconnection lines 140 may be disposed above the third interconnection lines 130.

Each of the first, second, third and fourth interconnection lines 110, 120, 130 and 140 may have a desired (or alternatively, predetermined) width in an X-axis direction and may extend in a Y-axis direction. The first interconnection lines 110 may be arrayed in the X-axis direction and may be spaced apart from each other, and the second interconnection lines 120 may be arrayed in the X-axis direction and may be spaced apart from each other. Similarly, the third interconnection lines 130 may be arrayed in the X-axis direction and may be spaced apart from each other, and the fourth interconnection lines 140 may be arrayed in the X-axis direction and may be spaced apart from each other.

Each of the first, second, third and fourth interconnection lines 110, 120, 130 and 140 may have a first end and a second end opposite to the first end. First protrusions 111 may be disposed to extend from respective ones of the first ends of the first interconnection lines 110 in the X-axis direction. Similarly, second protrusions 121 may be disposed to extend from respective ones of the first ends of the second interconnection lines 120 in the X-axis direction. Further, third protrusions 131 may be disposed to extend from respective ones of the second ends of the third interconnection lines 130 in the X-axis direction. The second ends of the third interconnection lines 130 may be disposed above the second ends of the first and second interconnection lines 110 and 120. Fourth protrusions 141 may be disposed to extend from respective ones of the second ends of the fourth interconnection lines 140 in the X-axis direction. The second ends of the fourth interconnection lines 140 may be disposed above the second ends of the first and second interconnection lines 110 and 120.

Interlayer insulation layers may be disposed between the first and second interconnection lines 110 and 120, between the second and third interconnection lines 120 and 130, and/or between the third and fourth interconnection lines 130 and 140. However, the interlayer insulation layers are not shown in FIGS. 4A, 4B, 4C and 4D in order to clearly illustrate an internal structure of the inductor.

The first to fourth interconnection lines 110, 120, 130 and 140 may be disposed to be parallel with the Y-axis direction, as illustrated in FIG. 4A. However, the inventive concept may not be limited to the above description.

The first to fourth interconnection lines 110, 120, 130 and 140 may be electrically connected to each other thorough first lower vias 115, second lower vias 116, first intermediate vias 125, second intermediate vias 126, third intermediate vias 127, fourth intermediate vias 128, first upper vias 135 and second upper vias 136. Each of the vias 115, 116, 125, 126, 127, 128, 135 and 136 may include metal material such as copper, aluminum and/or tungsten.

Intermediate connectors 122 and 123 may be disposed between the lower vias 115 and 116 and the intermediate vias 126 and 128, and upper connectors 132 and 133 may be disposed between the intermediate vias 126 and 128 and the upper vias 135 and 136.

In some example embodiments, first intermediate connectors 122 may be disposed between the first lower vias 115 and the second intermediate vias 126. The first intermediate connectors 122 may electrically connect the first lower vias 115 to the second intermediate vias 126. The first intermediate connectors 122 may be disposed at the same level as the second interconnection lines 120 and may be spaced apart from the second interconnection lines 120.

Second intermediate connectors 123 may be disposed between the second lower vias 116 and the fourth intermediate vias 128. The second intermediate connectors 123 may electrically connect the second lower vias 116 to the fourth intermediate vias 128. The second intermediate connectors 123 may be disposed at the same level as the second interconnection lines 120 and may be spaced apart from the second interconnection lines 120.

First upper connectors 132 may be disposed between the second intermediate vias 126 and the first upper vias 135. The first upper connectors 132 may electrically connect the second intermediate vias 126 to the first upper vias 135. The first upper connectors 132 may be disposed at the same level as the third interconnection lines 130 and may be spaced apart from the third interconnection lines 130.

Second upper connectors 133 may be disposed between the fourth intermediate vias 128 and the second upper vias 136. The second upper connectors 133 may electrically connect the fourth intermediate vias 128 to the second upper vias 136. The second upper connectors 133 may be disposed at the same level as the third interconnection lines 130 and may be spaced apart from the third interconnection lines 130.

Each of the first and second intermediate connectors 122 and 123 and the first and second upper connectors 132 and 133 may include metal material such as copper, aluminum and/or tungsten.

The first interconnection lines 110 may be electrically connected to the fourth interconnection lines 140.

In some example embodiments, the first end of the first interconnection line 110 may be electrically connected to the first end of the fourth interconnection line 140 through the first protrusion 111, the first lower via 115, the first intermediate connector 122, the second intermediate via 126, the first upper connector 132 and the first upper via 135. The second end of the first interconnection line 110 may be electrically connected to the second end of another fourth interconnection line 140 adjacent to the fourth interconnection line 140 above the first interconnection line 110 through the second lower via 116, the second intermediate connector 123, the fourth intermediate via 128, the second upper connector 133, the second upper via 136 and the fourth protrusion 141. Thus, the plurality of first interconnection lines 110 and the plurality of fourth interconnection lines 140 may be connected to each other through the vias 115, 116, 126, 128, 135 and 136 and the connectors 122, 123, 132 and 133, thereby constituting a first spiral structure. A plane surrounded by each loop of the first spiral structure may be substantially perpendicular to the substrate 100.

Alternatively, the first and fourth interconnection lines 110 and 140 may be connected to each other through the vias without use of the first to fourth protrusions 111, 121, 131 and 141. Accordingly, the connection structure of the first and fourth interconnection lines 110 and 140 may be embodied in many different forms.

The second interconnection lines 120 may be electrically connected to the third interconnection lines 130.

In some example embodiments, the first end of the second interconnection line 120 may be electrically connected to the first end of the third interconnection line 130 above the second interconnection line 120 through the second protrusion 121 and the first intermediate via 125. The second end of the second interconnection line 120 may be electrically connected to the second end of another third interconnection line 130 adjacent to the third interconnection line 130 above the second interconnection line 120 through the third intermediate via 127 and the third protrusion 131. Thus, the plurality of second interconnection lines 120 and the plurality of third interconnection lines 130 may be connected to each other through the intermediate vias 125 and 127, thereby constituting a second spiral structure. A plane surrounded by each loop of the second spiral structure may be substantially perpendicular to the substrate 100.

Alternatively, the second and third interconnection lines 120 and 130 may be connected to each other through the vias without use of the second and third protrusions 121 and 131. Accordingly, the connection structure of the second and third interconnection lines 120 and 130 may be embodied in many different forms.

As illustrated in FIGS. 4B and 4C, the first interconnection lines 110 may be disposed to overlap with the second interconnection lines 120 in a plan view, and the third interconnection lines 130 may be disposed to overlap with the fourth interconnection lines 140 in a plan view. That is, the third and fourth interconnection lines 130 and 140 may be disposed between the first interconnection lines 110 (or the second interconnection lines 120). Thus, the first and fourth interconnection lines 110 and 140 may be serially connected to each other to constitute the first spiral structure. However, the inventive concept may not be limited to the above descriptions. Accordingly, the connection structure of the first and fourth interconnection lines 110 and 140 may be embodied in many different forms.

Consequently, the first interconnection lines 110 and the fourth interconnection lines 140 may be serially connected to each other to constitute the first spiral structure, and the second interconnection lines 120 and the third interconnection lines 130 may also be serially connected to each other to constitute the second spiral structure.

As illustrated in FIG. 4D, the second and third interconnection lines 120 and 130 may be shorter in length than the first and fourth interconnection lines 110 and 140. Thus, the second spiral structure composed of the second and third interconnection lines 120 and 130 may be disposed in the first spiral structure composed of the first and fourth interconnection lines 110 and 140.

Referring again to FIG. 4A, the first, second, third and fourth interconnection lines 110, 120, 130 and 140 may be disposed to constitute vertical type spiral structures. That is, the first interconnection lines 110 and the fourth interconnection lines 140 may constitute the first vertical type spiral structure, and the second interconnection lines 120 and the third interconnection lines 130 may constitute the second vertical type spiral structure. Thus, the first, second, third and fourth interconnection lines 110, 120, 130 and 140 may constitute a double spiral structure.

The interconnection lines 110, 120, 130 and 140, the vias 115, 116, 125, 126, 127, 128, 135 and 136, and the connectors 122, 123, 132 and 133 may constitute a coil-shaped structure, and both terminals of the coil-shaped structure may be connected to circuits. Thus, the coil-shaped structure may act as an inductor.

The inductor according to the above example embodiment may have coils which are substantially perpendicular to the substrate 100. Thus, semiconductor elements (e.g., transistors or the like) formed around the inductor may be less influenced by electrical signals flowing through the inductor. Further, a planar area that the vertical type inductor occupies may be minimized to increase the integration density of a semiconductor device and/or to provide a high inductance in a limited planar area.

The inductor according to the above example embodiment may be formed to have vertical coils, as described above. Thus, the intensity of the magnetic field generated from the inductor may be increased to improve the efficiency of the inductor.

The inductor illustrated in FIGS. 4A to 4D may provide a double spiral structure. However, the inventive concept may not be limited to example embodiments illustrated in FIGS. 4A to 4D. For example, some interconnection lines may be additionally disposed above the fourth interconnection lines 140 to constitute a multi-spiral structure. That is, although not shown in the drawings, fifth interconnection lines and sixth interconnection lines may further disposed above the fourth interconnection lines 140. In this case, the first interconnection lines 110 and the sixth interconnection lines may constitute a first spiral structure, and the second interconnection lines 120 and the fifth interconnection lines may constitute a second spiral structure. Further, the third interconnection lines 130 and the fourth interconnection lines 140 may constitute a third spiral structure.

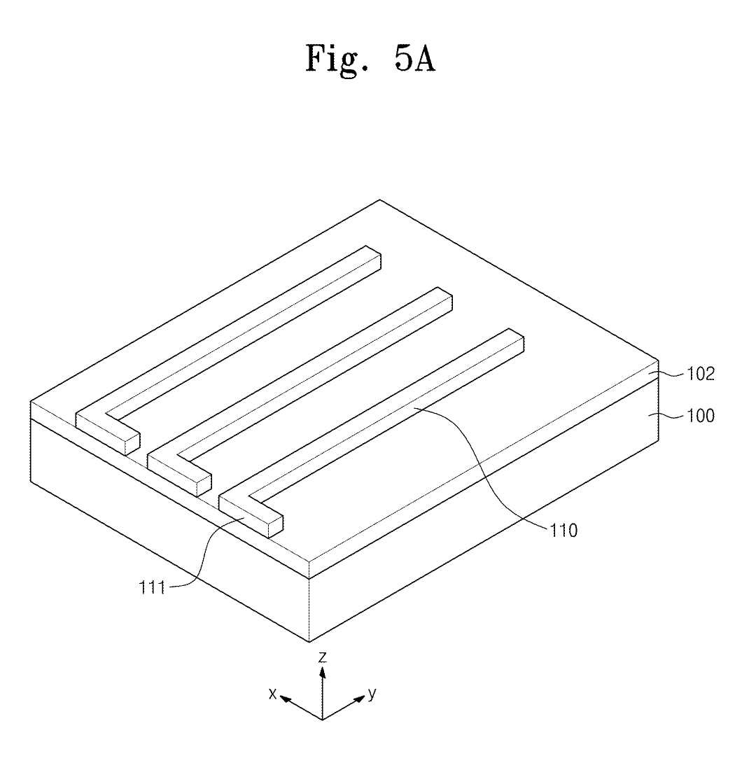

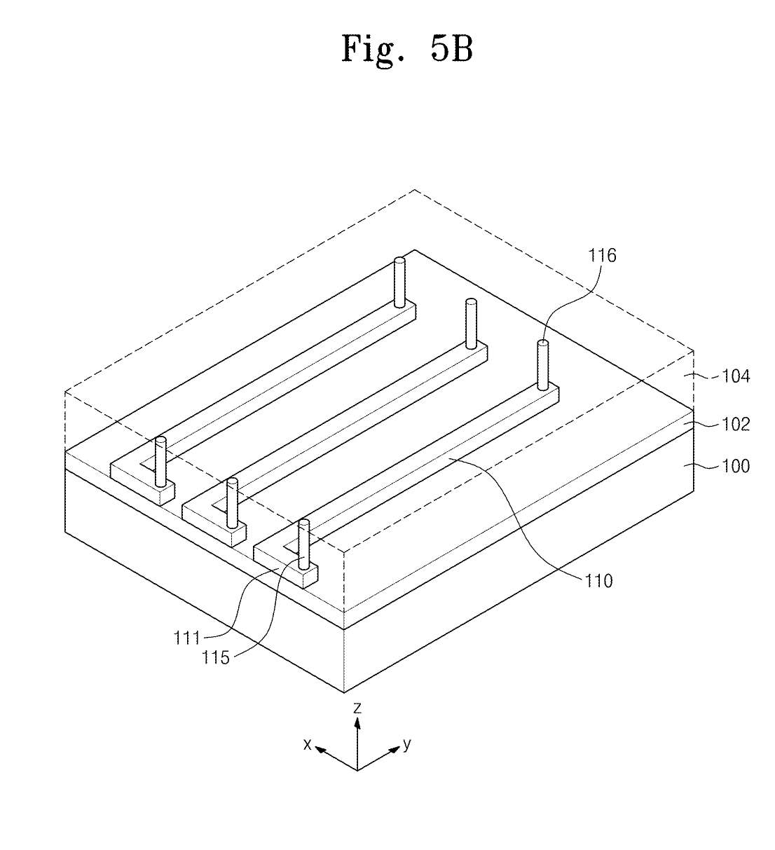

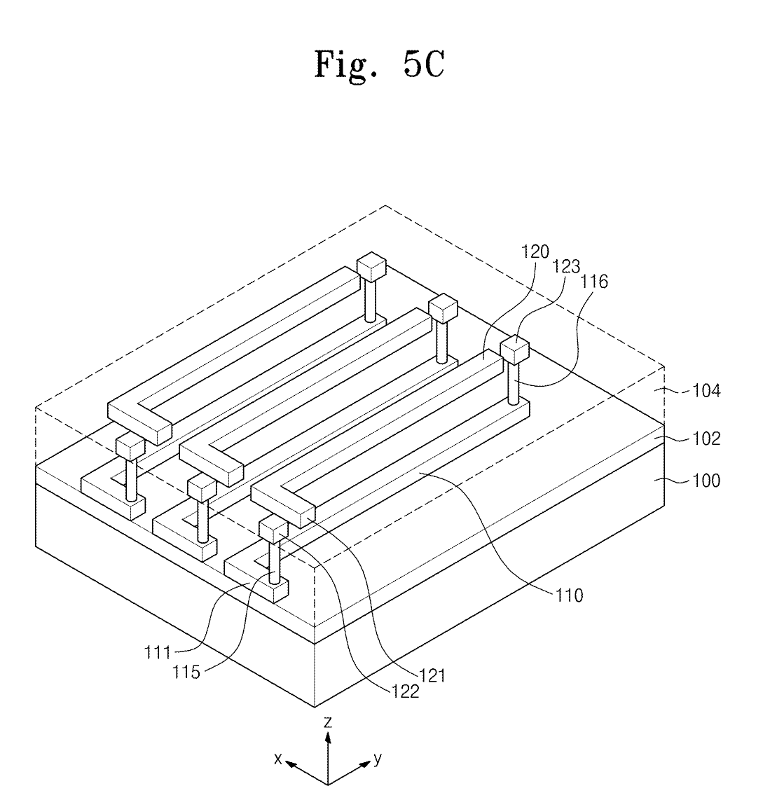

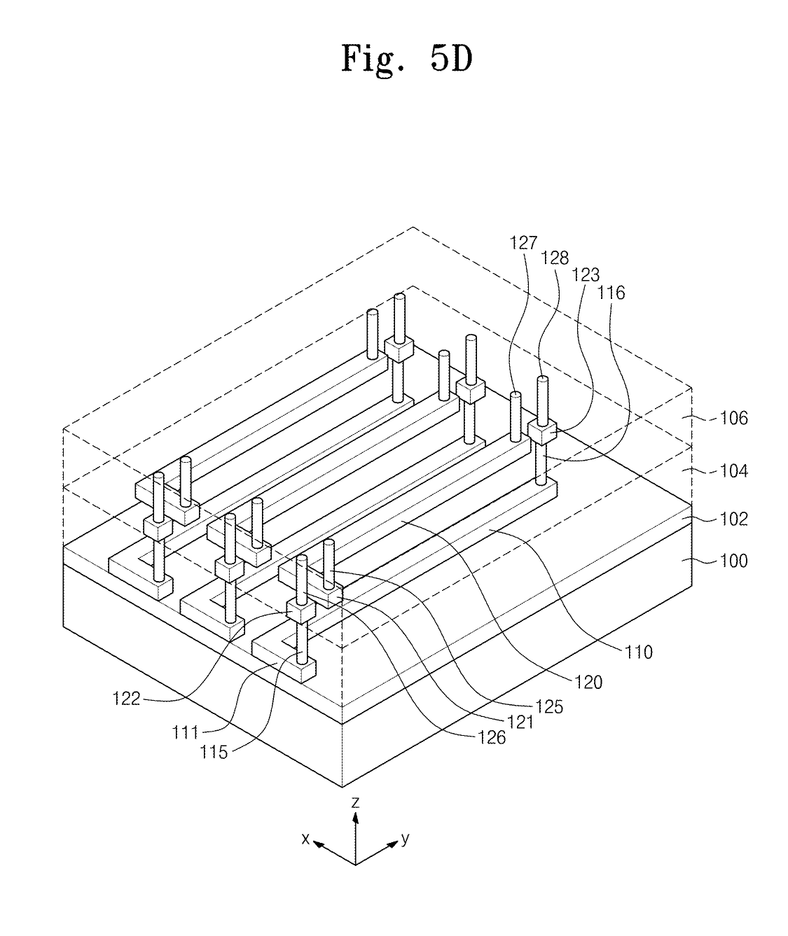

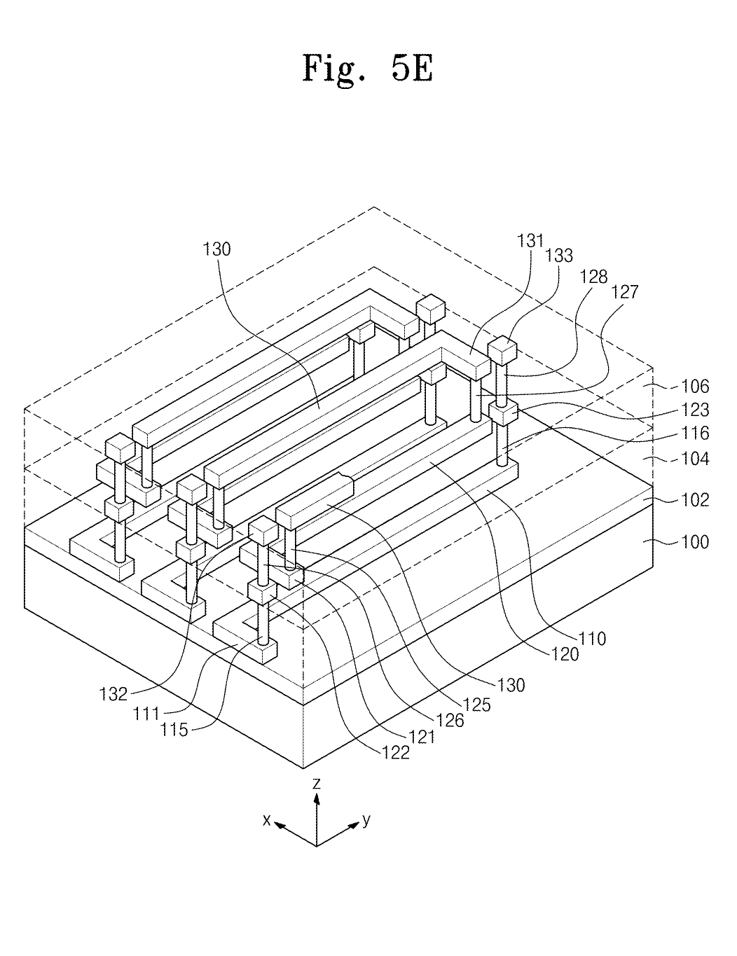

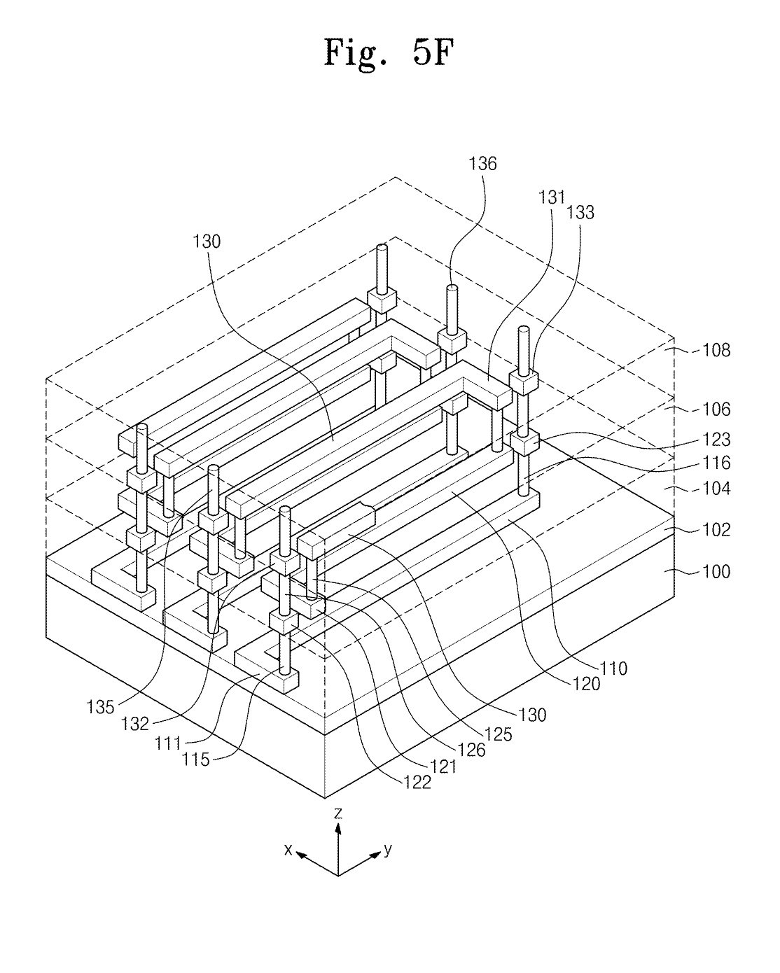

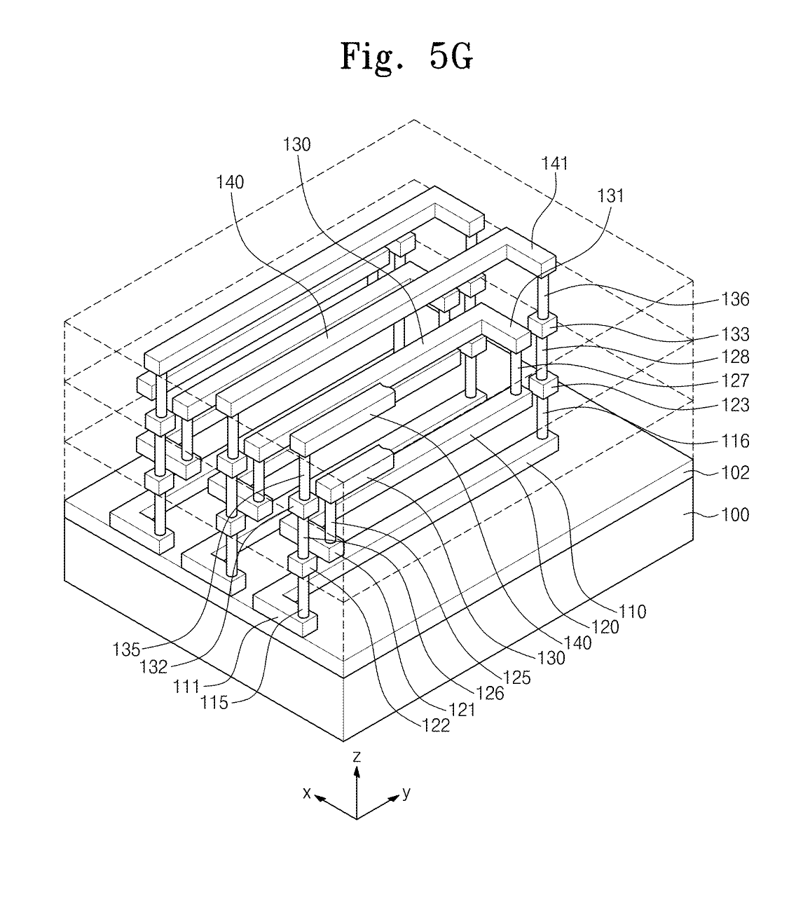

FIGS. 5A to 5G are perspective views illustrating a method of forming an inductor according to some example embodiments.

Processes illustrated in FIGS. 5A to 5D are the same as illustrated in FIGS. 2A to 2D. Thus, the processes illustrated in FIGS. 5A to 5D will be briefly described hereinafter.

Referring to FIG. 5A, an insulation layer 102 may be formed on a substrate 100. First interconnection lines 110 and first protrusions 111 may be formed on the insulation layer 102.

Referring to FIG. 5B, a first interlayer insulation layer 104 may be formed to cover the first interconnection lines 110. First lower vias 115 and second lower vias 116 may be formed to penetrate the first interlayer insulation layer 104. The first lower vias 115 may be formed on respective ones of the first protrusions 111 that protrude from first ends of the first interconnection lines 110, and the second lower vias 116 may be formed on respective ones of second ends of the first interconnection lines 110. Therefore, each of the first and second lower vias 115 and 116 may be electrically connected to any one of the first interconnection lines 110.

Referring to FIG. 5C, second interconnection lines 120, second protrusions 121, first intermediate connectors 122, and second intermediate connectors 123 may be formed on the first interlayer insulation layer 104.

The first intermediate connectors 122 may be formed on respective ones of the first lower vias 115 and may be electrically connected to respective ones of the first lower vias 115. The second intermediate connectors 123 may be formed on respective ones of the second lower vias 116 and may be electrically connected to respective ones of the second lower vias 116.

Referring to FIG. 5D, a second interlayer insulation layer 106 may be formed to cover the second interconnection lines 120, the first intermediate connectors 122 and the second intermediate connectors 123. First intermediate vias 125, second intermediate vias 126, third intermediate vias 127 and fourth intermediate vias 128 may be formed to penetrate the second interlayer insulation layer 106.

The first intermediate vias 125 may be formed on respective ones of the second protrusions 121 and may be electrically connected to respective ones of the second protrusions 121. The second intermediate vias 126 may be formed on respective ones of the first intermediate connectors 122 and may be electrically connected to respective ones of the first intermediate connectors 122. The third intermediate vias 127 may be formed on respective ones of second ends of the second interconnection lines 120 and may be electrically connected to respective ones of the second ends of the second interconnection lines 120. The fourth intermediate vias 128 may be formed on respective ones of the second intermediate connectors 123 and may be electrically connected to respective ones of the second intermediate connectors 123.

Referring to FIG. 5E, third interconnection lines 130 may be formed on the second interlayer insulation layer 106. Each of the third interconnection lines 130 may be formed to have a desired (or alternatively, predetermined) width in the X-axis direction and to extend in the Y-axis direction. That is, the third interconnection lines 130 may be formed to be parallel with the Y-axis direction. The third interconnection lines 130 may be arrayed in the X-axis direction and may be spaced apart from each other.

In some example embodiments, the third interconnection lines 130 may be formed to extend in the Y-axis direction and first ends of the third interconnection lines 130 may be in contact with respective ones of the first intermediate vias 125. Thus, each of the third interconnection lines 130 may be electrically connected to any one of the second interconnection lines 120 through the first intermediate via 125 and the second protrusion 121.

Third protrusions 131 may be formed to extend from respective ones of second ends of the third interconnection lines 130 in the X-axis direction. Thus, the third protrusions 131 may be disposed above the second ends of the first and second interconnection lines 110 and 120.

First upper connectors 132 may be formed on the second interlayer insulation layer 106. The first upper connectors 132 may be formed to contact respective ones of the second intermediate vias 126 and may be electrically connected to respective ones of the second intermediate vias 126. The first upper connectors 132 may be formed to be adjacent to respective ones of the first ends of the third interconnection lines 130 and to be spaced apart from respective ones of the first ends of the third interconnection lines 130.

Second upper connectors 133 may be formed on the second interlayer insulation layer 106. The second upper connectors 133 may be formed to contact respective ones of the fourth intermediate vias 128 and may be electrically connected to respective ones of the fourth intermediate vias 128. The second upper connectors 133 may be formed to be adjacent to respective ones of the third protrusions 131 and to be spaced apart from respective ones of the third protrusions 131.

The third interconnection lines 130, the third protrusions 131, the first upper connectors 132 and the second upper connectors 133 may be formed by depositing a conductive layer on the second interlayer insulation layer 106 and by patterning the conductive layer. The conductive layer may be formed using a deposition process or a sputtering process. Alternatively, the third interconnection lines 130, the third protrusions 131, the first upper connectors 132 and the second upper connectors 133 may be formed in the second interlayer insulation layer 106 using a damascene process. The third interconnection lines 130, the third protrusions 131, the first upper connectors 132 and the second upper connectors 133 may be simultaneously formed.

Referring to FIG. 5F, a third interlayer insulation layer 108 may be formed to cover the third interconnection lines 130, the third protrusions 131, the first upper connectors 132 and the second upper connectors 133.

First upper vias 135 and second upper vias 136 may be formed in the third interlayer insulation layer 108. The first upper vias 135 and the second upper vias 136 may be formed by patterning the third interlayer insulation layer 108 to form via holes penetrating the third interlayer insulation layer 108, forming a conductive layer in the via holes and on the third interlayer insulation layer 108, and planarizing the conductive layer until the third interlayer insulation layer 108 is exposed.

The first upper vias 135 may be formed on respective ones of the first upper connectors 132 and may be electrically connected to respective ones of the first upper connectors 132. The second upper vias 136 may be formed on respective ones of the second upper connectors 133 and may be electrically connected to respective ones of the second upper connectors 133. The first and second upper vias 135 and 136 may be simultaneously formed.

Referring to FIG. 5G, fourth interconnection lines 140 may be formed on the third interlayer insulation layer 108. Each of the fourth interconnection lines 140 may be formed to have a desired (or alternatively, predetermined) width in the X-axis direction and to extend in the Y-axis direction. That is, the fourth interconnection lines 140 may be formed to be parallel with the Y-axis direction. The fourth interconnection lines 140 may be arrayed in the X-axis direction and may be spaced apart from each other. The fourth interconnection lines 140 may be formed such that first ends of the fourth interconnection lines 140 may contact respective ones of the first upper vias 135. As such, the first end of each of the fourth interconnection lines 140 may be electrically connected to any one of the first interconnection lines 110 through the first upper via 135, the first upper connector 132, the second intermediate via 126, the first intermediate connector 122, the first lower via 115 and the first protrusion 111.

Fourth protrusions 141 may be formed to extend from respective ones of second ends of the fourth interconnection lines 140 in the X-axis direction. Thus, the fourth protrusions 141 may be disposed above the second ends of the first and second interconnection lines 110 and 120. The fourth protrusions 141 may be formed to contact respective ones of the second upper vias 136. As such, the second end of each of the fourth interconnection lines 140 may be electrically connected to any one of the first interconnection lines 110 through the fourth protrusion 141, the second upper via 136, the second upper connector 133, the fourth intermediate via 128, the second intermediate connector 123 and the second lower via 116.

Consequently, the interconnection lines 110, 120, 130 and 140, the vias 115, 116, 125, 126, 127, 128, 135 and 136, and the connectors 122, 123, 132 and 133 may constitute a coil-shaped structure, and both terminals of the coil-shaped structure may be connected to circuits. Thus, the coil-shaped structure may act as an inductor.

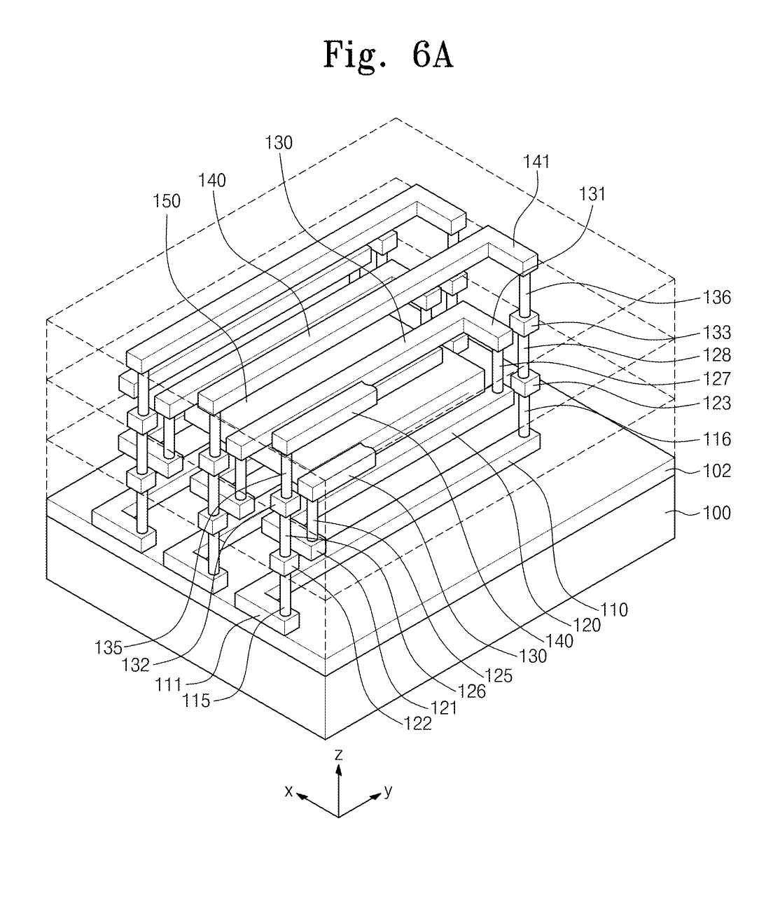

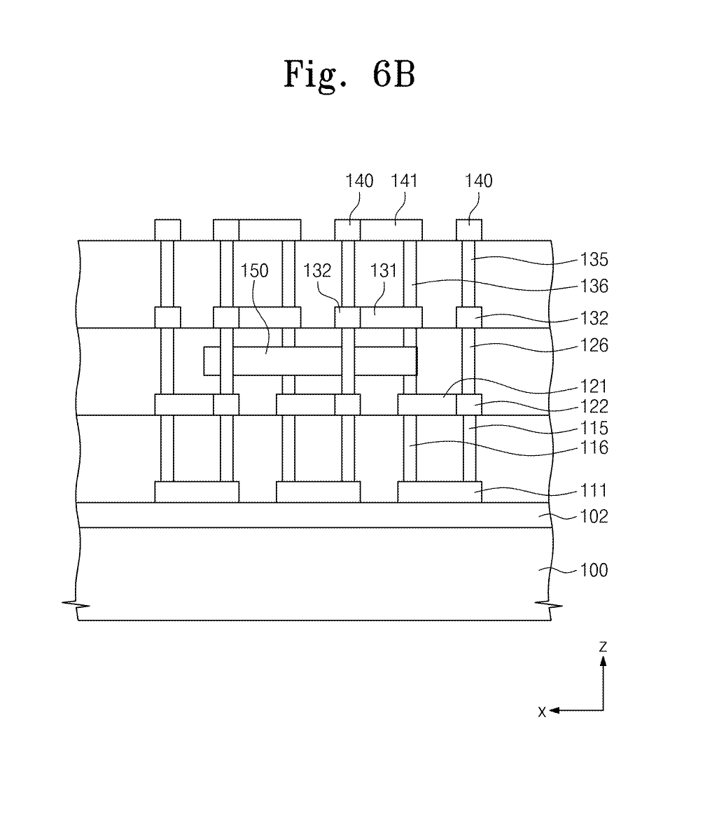

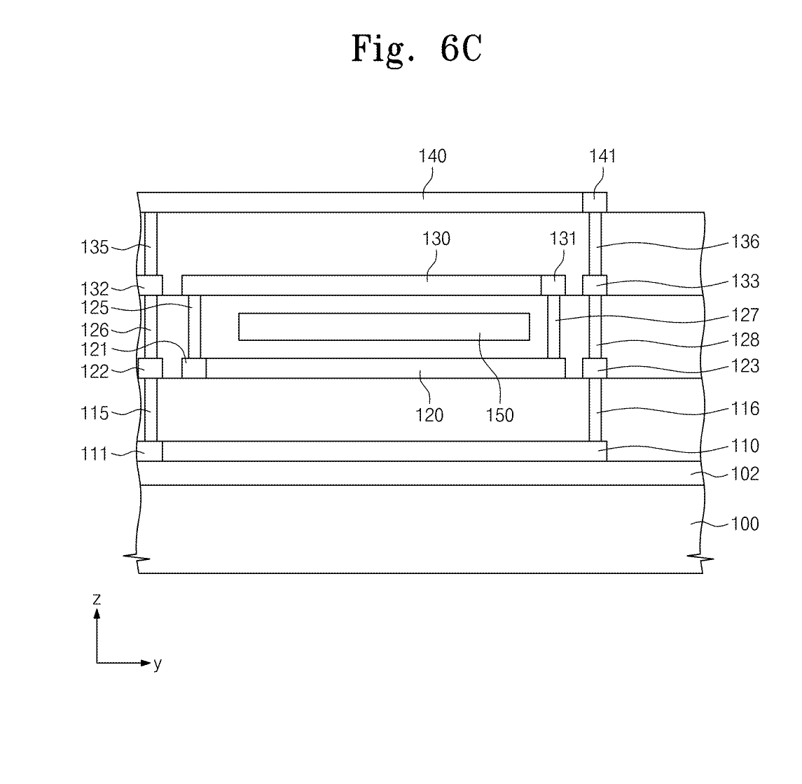

FIG. 6A is a perspective view illustrating an inductor according to some example embodiments. FIG. 6B is a front view of the inductor viewed along a Y-axis of FIG. 6A, and FIG. 6C is a side view of the inductor viewed along an X-axis of FIG. 6A.

Referring to FIGS. 6A, 6B and 6C, an inductor according to the example embodiment of FIGS. 6A, 6B and 6C may have the similar structure to the inductor described with reference to FIGS. 4A, 4B, 4C and 4D. The inductor according to example embodiments may further include an inductor core 150 disposed in coils constituting the inductor as compared to the example embodiment illustrated in FIGS. 4A to 4D. Thus, for the purpose of simplification in explanation, descriptions to the same components as illustrated in previous example embodiments will be omitted or briefly mentioned.

The inductor core 150 may include ferromagnetic material. For example, the inductor core 150 may include at least one of iron (Fe), cobalt (Co), nickel (Ni), tantalum (Ta), barium (Ba) and zinc (Zn).

The inductor core 150 may be disposed in the second interlayer insulation layer 106. The inductor core 150 may be formed using an electro-plating process or a deposition process.

The inductor core 150 may be surrounded by coils having a spiral structure and may be spaced apart from the coils. That is, the inductor core 150 may be spaced apart from the first interconnection lines 110, the second interconnection lines 120, the third interconnection lines 130, the fourth interconnection lines 140 and the vias 115, 116, 125, 126, 127, 128, 135 and 136.

According to some example embodiments, the inductor core 150 may include ferromagnetic material. Thus, when a current flows through the inductor, magnetic dipoles in the inductor core 150 may be arrayed to be parallel with a specific direction. Accordingly, the inductance of the inductor may be more increased.

According to example embodiments set forth above, a plane surrounded by each of spiral coils constituting inductors may be substantially perpendicular to a substrate. Thus, the inductance of the inductor may be increased in a limited planar area and the integration density of a semiconductor device including the inductor may also be increased in a limited planar area. Further, since the coils of the inductor are substantially perpendicular to the substrate, semiconductor elements (e.g., transistors or the like) formed under the inductor may be less influenced by electrical signals flowing through the inductor.

In addition, the inductors according to the above example embodiments may be formed to have vertical coils, as described above. Thus, the intensity of the magnetic field generated from the inductor may be increased to improve the efficiency of the inductor.

Moreover, the inductors according to the above example embodiments may include an inductor core in a region surrounded by the coils and the inductor core may include ferromagnetic material. Thus, the inductance of the inductors may be increased.

While example embodiments have been particularly shown and described, it will be understood by those of ordinary skill in the art that various changes in form and details may be made therein without departing from the spirit and scope of the present invention as defined by the following claims.

What is claimed is:

1. An inductor in a semiconductor device, the inductor comprising:
a first interconnection line on a substrate;
a second interconnection line on the first interconnection line;
first and second common interconnection lines on the second interconnection line, where the first and second common interconnection lines are adjacent to each other;
a first via connecting a first end of the first interconnection line to a first end of the first common interconnection line;
a second via connecting a second end of the first interconnection line to a second end of the second common interconnection line;
a third via connecting a first end of the second interconnection line to the first end of the first common interconnection line; and
a fourth via connecting a second end of the second interconnection line to the second end of the second common interconnection line;
wherein the first interconnection line, the second interconnection line, and the first and second common interconnection lines extend in a first direction that is parallel to a surface of the substrate.

2. The inductor of claim 1, further comprising:
a first protrusion extending from the first end of the first interconnection line in a second direction intersecting the first direction;
wherein the first common interconnection line is electrically connected to the first interconnection line through the first protrusion and the first via.

3. The inductor of claim 1, further comprising:
a second protrusion extending from the first end of the second interconnection line in a second direction intersecting the first direction;
wherein the first common interconnection line is electrically connected to the second interconnection line through the second protrusion and the first via.

4. The inductor of claim 1, further comprising:
a third protrusion and a fourth protrusion extending from the second end of the second common interconnection line in a second direction intersecting the first direction;
wherein the second common interconnection line is electrically connected to the first interconnection line through the fourth protrusion and the second via, and
wherein the second common interconnection line is electrically connected to the second interconnection line through the third protrusion and the fourth via.

5. The inductor of claim 1, wherein each of the first and second vias includes an upper via, a lower via, and a connector between the upper and lower vias,
wherein the connector is at a same level as the second interconnection line, and
wherein the connector is spaced apart from second interconnection line.

6. The inductor of claim 1, further comprising:
an inductor core under the first and second common interconnection lines;
wherein the inductor core is spaced apart from the first and second common interconnection lines, and
wherein the inductor core is spaced apart from the first to fourth vias.

7. The inductor of claim 6, wherein the inductor core is between the first interconnection line and the second interconnection line, or
wherein the inductor core is between the second interconnection line and the first and second common interconnection lines.

8. The inductor of claim 6, wherein the inductor core includes ferromagnetic material.

9. An inductor in a semiconductor device, the inductor comprising:
a first interconnection line on a substrate;
a second interconnection line on the first interconnection line;
third and fourth interconnection lines on the second interconnection line;
fifth and sixth interconnection lines on the third and fourth interconnection lines;
a first via connecting a first end of the first interconnection line to a first end of the fifth interconnection line;
a second via connecting a second end of the first interconnection line to a second end of the sixth interconnection line;
a third via connecting a first end of the second interconnection line to a first end of the third interconnection line; and
a fourth via connecting a second end of the second interconnection line to a second end of the fourth interconnection line;
wherein the first to sixth interconnection lines extend in a first direction that is parallel to a surface of the substrate.

10. The inductor of claim 9, further comprising:
a first protrusion extending from the first end of the first interconnection line in a second direction intersecting the first direction;
wherein the first interconnection line is electrically connected to the fifth interconnection line through the first protrusion and the first via.

11. The inductor of claim 9, further comprising:
a second protrusion extending from the first end of the second interconnection line in a second direction intersecting the first direction;
wherein the second interconnection line is electrically connected to the third interconnection line through the second protrusion and the third via.

12. The inductor of claim 9, further comprising:
a third protrusion extending from the second end of the fourth interconnection line in a second direction intersecting the first direction;
wherein the second interconnection line is electrically connected to the fourth interconnection line through the third protrusion and the fourth via.

13. The inductor of claim 9, further comprising:
a fourth protrusion extending from the second end of the sixth interconnection line in a second direction intersecting the first direction;
wherein the first interconnection line is electrically connected to the sixth interconnection line through the fourth protrusion and the second via.

14. The inductor of claim 9, further comprising:
an inductor core between the second and third interconnection lines;
wherein the inductor core is spaced apart from the first to sixth interconnection lines, and
wherein the inductor core is spaced apart from the first to fourth vias.

15. The inductor of claim 14, wherein the inductor core includes ferromagnetic material.

16. An inductor in a semiconductor device, the inductor comprising:
a first spiral structure; and
a second spiral structure;
wherein the first spiral structure includes:
a first interconnection line on a substrate;
first and second common interconnection lines adjacent to each other;
a first via connecting a first end of the first interconnection line to a first end of the first common interconnection line; and
a second via connecting a second end of the first interconnection line to a second end of the second common interconnection line;
wherein the second spiral structure includes:
a second interconnection line on the first interconnection line;
the first and second common interconnection lines;
a third via connecting a first end of the second interconnection line to the first end of the first common interconnection line; and
a fourth via connecting a second end of the second interconnection line to the second end of the second common interconnection line;
wherein the first and second common interconnection lines are on the second interconnection line.

17. The inductor of claim 16, wherein a first distance, from the first end of the first interconnection line to the second end of the first interconnection line, is greater than a second distance, from the first end of the second interconnection line to the second end of the second interconnection line.

18. The inductor of claim 16, wherein a cross-sectional area of the first spiral structure is greater than a cross-sectional area of the second spiral structure.

19. The inductor of claim 16, further comprising:
an inductor core between the first interconnection line and the second interconnection line, or between the second interconnection line and the first and second common interconnection lines.

20. The inductor of claim 19, wherein the first spiral structure at least partially surrounds the inductor core, and
wherein the second spiral structure at least partially surrounds the inductor core.
